(19) United States
(12) Patent Application Publication
(10) Pub. No.: US 2002/0031888 A1
(43) Pub. Date: Mar. 14, 2002

(54) Method for reducing processing steps when fabricating a flash memory array using a blank implant

(76) Inventors: Hao Fang, Cupertino, CA (US); Masaaki Higashitani, Sunnyvale, CA (US); Narbeh Derhacobian, Belmont, CA (US)

Correspondence Address: SAWYER LAW GROUP LLP, P.O. Box 51418, Palo Alto, CA, 94303, US

(21) Appl. No.: 09/915,941

(22) Filed: Jul. 25, 2001

Related U.S. Application Data
(62) Division of application No. 09/491,531, filed on Jan. 26, 2000, now abandoned.

(51) Int. Cl. H01L 21/336

(52) U.S. Cl. 438/258

(57) ABSTRACT

A method for reducing processing steps when fabricating a flash memory array comprising a core area and a periphery area having high-voltage transistors is disclosed. The method includes the steps of depositing a layer of type-2 polysilicon and mask, and selectively etching the type-2 polysilicon. The method further includes the steps of performing a blank implant before removal of the mask over both the core area and the periphery area, wherein deposition of a high-voltage implant mask but is unnecessary. In a preferred embodiment, a NAND flash memory array is fabricated and the blank implant comprises phosphorus at a dose of approximately 3×10¹² cm⁻² at 30 keV.

### FIELD OF THE INVENTION

The present invention relates to flash memory arrays, and more particularly to the fabrication of flash memory arrays using a blank low-dose implant.

### BACKGROUND OF THE INVENTION

A flash memory array typically includes a core area and a periphery area. The core area includes memory transistors, while the periphery area contains both low-voltage transistors for handling logic and switching circuitry, and high-voltage transistors for handling high-voltages encountered during flash memory programming and erase operations.

A high-voltage transistor is required to operate at a high-voltage of up to 27 volts on the transistor's source and drain. In order to achieve this requirement, high-voltage transistors must include drain structures, referred to as lightly doped drains (LDD), that are formed by performing a LDD implant comprising less than 1×10¹³ cm⁻². In contrast, the memory transistors and the low-voltage transistors receive implants comprising 6×10¹⁴ to 4×10¹⁵ cm⁻² and 2×10¹³ to 2×10¹⁴ cm⁻², respectively. Because the LDD implant is so different from implants used in both the core area and the periphery area containing low-voltage transistors, conventional methods for fabricating the flash memory array have required that these areas be covered with a high-voltage implant mask before the LDD implant is performed.

Although the high-voltage LDD mask sufficiently protects the memory transistors and the low-voltage transistors from the LDD implant, depositing the LDD mask is expensive and must be removed after the LDD implant, resulting in extra processing steps.

Accordingly, what is needed is a method for performing the high-voltage LDD implant during memory array fabrication that eliminates the need for a high-voltage LDD mask.

### SUMMARY OF THE INVENTION

The present invention provides a method for reducing processing steps when fabricating a flash memory array comprising a core area and a periphery area having high-voltage transistors is disclosed. The method includes the steps of depositing a layer of type-2 polysilicon and mask, and selectively etching the type-2 polysilicon. The method further includes the steps of performing a blank implant before removal of the mask over both the core area and the periphery area, wherein deposition of a high-voltage implant mask is unnecessary. In a preferred embodiment, a NAND flash memory array is fabricated and the blank implant comprises phosphorus at a dose of approximately 3×10¹² cm⁻² at 30 keV.

According to the present invention, the method for fabricating the flash memory array saves processing steps and reduces the cost of memory array fabrication.

### BRIEF DESCRIPTION OF THE DRAWINGS

FIG. 1 is a cross-sectional view of a flash memory array during fabrication.

FIG. 2 is flow chart illustrating the process fabricating a flash memory array in accordance with the present invention.

### DETAILED DESCRIPTION

The presidential provides improved method for fabricating a memory array. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

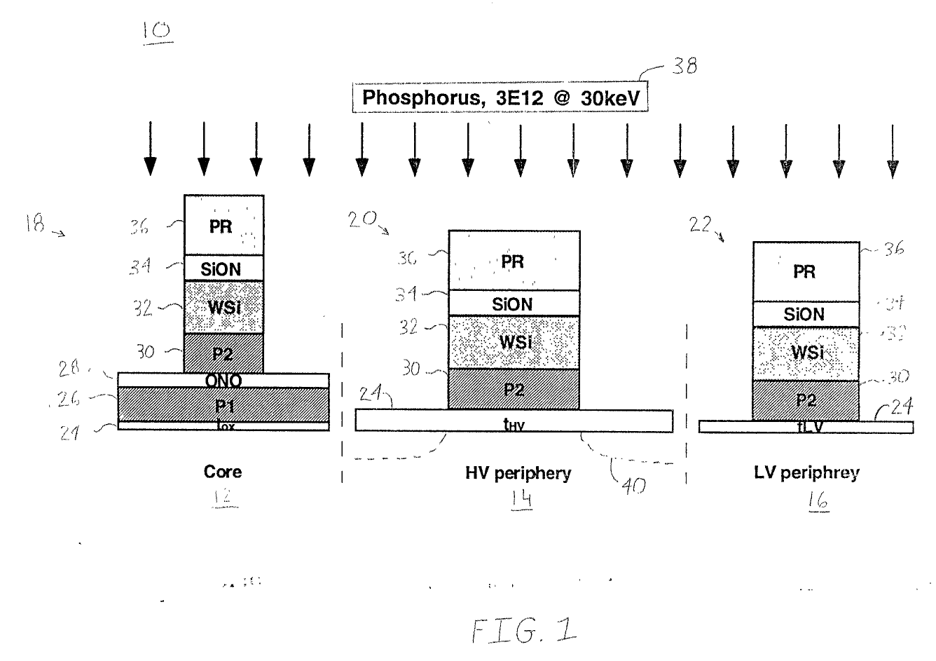

FIG. 1 is a cross-sectional view of a flash memory array during fabrication. The flash memory array 10 includes a core area 12, a high-voltage periphery area 14, and a low-voltage periphery area 16. The core area includes memory transistors 18, while the high-voltage periphery area 14 and low-voltage periphery area 16 include high-voltage transistors 20 and low-voltage transistors 22, respectively. In a preferred embodiment, the memory array 10 is a NAND application.

The present invention provides a method for reducing memory fabrication processing steps by providing an improved LDD implant that eliminates the need for a high-voltage LDD mask.

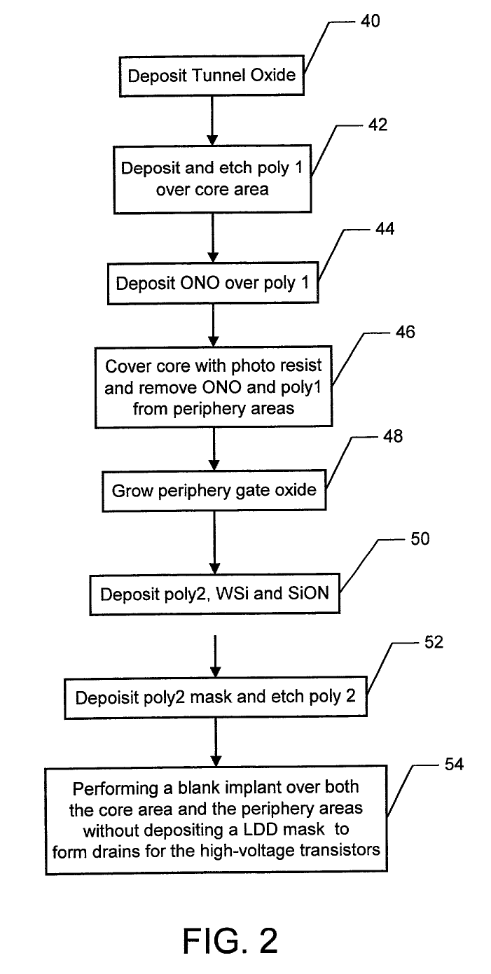

FIG. 2 is flow chart illustrating the process fabricating a flash memory array 10 in accordance with the present invention. Referring to both FIGS. 1 and 2, the process begins by depositing a layer of tunnel oxide 24 of varying thickness over a substrate in both the core area 12 and periphery areas 14 and 16 in step 40. Next, a layer of type-1 polysilicon (poly1) 26 is deposited in both the core area 12 and periphery areas 14 and 16 and selectively etched to form floating gates for the memory transistors 18 in step 42. After the poly1 26 is patterned, a layer of oxide nitride (ONO) 28 is deposited over the poly1 layer 26 in step 44.

After the layer of ONO 28 is deposited, the core area 12 is covered by photo resist and the ONO 28 and poly1 layer 26 are removed in the periphery areas 14 and 16 in step 46. Then, a periphery gate oxide is grown in step 48, and a type-2 layer of polysilicon 30 (poly2) is deposited in all areas followed by a deposition tungsten silicide (WSi) 32 and silicon nitride (SiON) 34 layers in step 50. After all gate stacks are formed, photo resist 36 is deposited to form a poly2 mask, and the poly2 30, WSi 32, and SiON 34 are etched over the core area 12 and periphery areas 14 and 16 to form word lines for the memory transistors 18 and gates for the high and low-voltage transistors 20 and 22 in step 52.

The next step in the process is the creation of drains 40 for the high-voltage transistors 20. In traditional fabrication processes, the poly2 mask would be removed before forming the drains 40 by performing the LDD implant. Therefore, the deposition of a high-voltage LDD mask was required over the core area 12 and the low voltage periphery area 16 to protect those areas from the LDD implant. Although the high-voltage LDD mask sufficiently protects the memory transistors 18 and the low-voltage transistors 22 from the LDD implant, depositing the LDD mask is expensive and must be removed after the LDD implant, resulting in extra processing steps.

Instead of depositing a high-voltage LDD mask, the present invention optimizes the high-voltage implant condition and performs a blank low energy and low dose implant 38 before the poly2 mask is removed over both the core area 12 and the periphery areas 14 and 16 without depositing a LDD mask in step 54. The term “blank” implant is used because no implant mask is required before performing the implant. The energy of the blank implant 38 of the present invention effectively forms the LDD drains 40 for the high-voltage transistors 20, but does not affect the core memory transistors 18 or the low-voltage transistors 22. In a preferred embodiment, the blank implant comprises phosphorus at a dose of approximately 3×10¹² cm⁻² at 30 keV.

The blank implant 38 has no effect on the core memory transistors 18 due to the optimized low energy of the blank implant and the ONO 28 and poly1 26 layers. In a preferred embodiment, the ONO layer 28 is approximately 150 to 200 angstroms in thickness, and the poly1 layer 26 is approximately 900 angstroms in thickness. Therefore, the blank implant 38 does not penetrate the ONO 28 and poly1 26 layers into the core memory transistors 18, and therefore has no impact on the core devices.

A further advantage of the present invention is that the selectivity of the poly2 layer 30 to the ONO layer 28 is usually high. Hence, the poly2 gate etch may be very easily optimized to stop on the ONO layer 28, further reducing the potential of the blank implant 38 penetrating the memory transistors 18.

The blank implant 38 also has no effect on the low-voltage transistors 22 because the blank implant dose is specially adjusted so that it is approximately ten times lower than typical N-LDD and P-LDD doses used to create N- and P-channel transistors. Therefore, the blank implant 38 should have negligible effect on the low-voltage periphery transistors 22.

Furthermore, this blank implant is performed after the poly2 etch, but before poly2 mask removal and hence it has no effect on the memory, periphery high-low voltage transistor gate doping and the channel doping under the gates because the gates areas remain covered during this blank implant.

A method for fabricating a NAND flash memory array using a blank low-dose implant has been disclosed. Although the present invention has been described in accordance with the embodiments shown, one of ordinary skill in the art will readily recognize that there could be variations to the embodiments and those variations would be within the spirit and scope of the present invention. Accordingly, many modifications may be made by one or ordinary skill in the art without departing from the spirit and scope of the appended claims.

What is claimed is:

1. A method for reducing processing steps when fabricating a flash memory array comprising a core area and a periphery area having high-voltage transistors, the method comprising the steps of:
(a) depositing a layer of type-2 polysilicon and mask over the core area and the periphery area;
(b) selectively etching the type-2 polysilicon to form transistor gates; and
(c) performing a blank implant before removal of the mask over both the core area and the periphery area, wherein deposition of a high-voltage implant mask is unnecessary.

2. The method claim 1 wherein the step of performing a blank implant implants phosphorus at a dose of approximately 3×10¹² cm⁻² at 30 keV that forms lightly doped drains for the high-voltage transistors.

3. The method of claim 2 wherein step (a) includes the step of:
(i) forming memory transistors in the core area by depositing the layer of type-2 polysilicon over a layer of ONO and a layer of type-1 polysilicon, wherein the layer of poly1 and the layer of ONO prevent the blank implant from penetrating the memory transistors.

4. The method of claim 3 wherein step (a) further includes the step of:
(ii) forming low-voltage transistors in the periphery area by depositing the layer of type-2 polysilicon over a layer of periphery gate oxide, wherein the blank implant has a negligible effect on the low-voltage transistors.

5. The method of claim 4 wherein step (a) further includes the step of:
(iii) depositing a layer of tungsten silicide, a layer of silicon nitride, and a layer of photo resist over the layer of type-2 polysilicon for the memory transistors, the high-voltage transistors and the low-voltage transistors.

6. The method claim 5 further for fabricating a NAND flash memory array.

7. A flash memory array, comprising;
a core area comprising memory transistors, the memory transistors including a layer of tunnel oxide, a layer of poly1, a layer of ONO, and a layer of poly2; and
a periphery area adjacent to the core area comprising high-voltage transistors, the high-voltage transistors including a layer of periphery gate oxide, a poly2 gate, a poly2 mask and LDD drains, wherein the LDD drains are formed by performing a blank implant after etching of the poly2 gate but before removal of the poly2 mask wherein a high-voltage implant mask is not required over the core area.

8. The flash memory array of claim 7 wherein the dosage of the blank implant is approximately 3×10¹² cm⁻² at 30 kev.

9. The flash memory array of claim 8 wherein the phosphorus is implanted during the blank implant.

10. The flash memory array of claim 9 wherein the periphery area further includes low-voltage transistors, wherein the low-voltage transistors are unaffected by the blank implant.
